(19) United States
(12) Patent Application Publication
(10) Pub. No.: US 2012/0024369 A1
(43) Pub. Date: Feb. 2, 2012

(54) PHOTO-CHEMICAL SOLAR CELL WITH NANONEEDLE ELECTRODE AND METHOD MANUFACTURING THE SAME

(76) Inventors: Cheng-Jye CHU, Kaohsiung (TW); Ruei-Ming Huang, Kaohsiung (TW); Hui-Ju Chuang, (US)

(21) Appl. No.: 13/187,775

(22) Filed: Jul. 21, 2011

(30) Foreign Application Priority Data
Jul. 28, 2010 (TW) 99124938

(51) Int. Cl. H01L 31/0224; H01L 31/18; B82Y 99/00

(52) U.S. Cl. 136/256; 438/85; 977/948; 257/E31.124

(57) ABSTRACT

A photo-chemical solar cell with nanoneedle electrode and a method manufacturing the same includes at least a working electrode, a counter electrode, an electrolyte layer and a photosensitized dye layer. The working electrode is an nanoneedle electrode formed from an nanoneedle semiconductor layer, wherein the nanoneedle semiconductor layer is prepared by sol-gel method at a low temperature to increase the specific surface area, adsorb more dye, increase the conductive ratio of the electrode, and thus improve the photo-current and the conversion efficiency.

### CROSS-REFERENCES TO RELATED APPLICATIONS

This non-provisional application claims priority under 35 U.S.C. § 119(a) on patent application Ser. No. 99124938 filed in Taiwan, R.O.C. on Jul. 28, 2010, the entire contents of which are hereby incorporated by reference.

### BACKGROUND

1. Technical Field

The disclosure generally relates to a solar cell and its manufacturing method, and more particularly to a photo-chemical solar cell with nanoneedle electrode and its manufacturing method.

2. Description of the Related Art

From the twentieth century to the twenty-first century, the shadow of the global energy crisis has been concealed, but it may become urgently apparent at any time. Since the Kyoto Protocol, the whole world has been committed to the research and development of alternative energy. Solar energy is the most popular solution in the development and utilization of new energy. It is estimated that the annual irradiation of the earth's surface by the sun is about a million times the entire human energy usage in a year. Global human energy needs could therefore be met even if only one percent of solar energy is completely collected and converted to electrical energy at a conversion rate of 10%.

The solar cell is a device that can translate the solar energy directly into the electrical energy. During the 1970s, the silicon solar cell first developed in the Bell Labs of United States was gradually developed further. The working principle of the silicon solar cells is based on the photovoltaic effect of semiconductors. Although the silicon solar cell has a high photovoltaic conversion efficiency, its complicated production process, expensive costs, and strict material demands, all limit its wider application. During the 1990s, photo-electrochemical cells applying nano crystals provided a new alternative for low-cost solar cells, in addition to the traditional silicon solar cells.

The dye sensitized solar cell (DSSC) is a representative of the photo-chemical solar cell. It uses a nanocrystalline semiconductor thin film formed on a surface of the substrate to adsorb a photosensitive dye forming the working electrode. The nanocrystalline semiconductor film is typically titanium dioxide or zinc oxide, but it is better to use titanium dioxide. Since the energy bandgap of titanium dioxide is 3.2 eV, it is understood that the absorbed number of photons of the titanium dioxide of the dye-sensitized solar cell cannot be increased. A large number of photosensitive dyes adsorbed on titanium dioxide can effectively improve the energy conversion efficiency. The working principle of a dye-sensitized solar cell is that when the dye molecules absorb sunlight, the electrons transit to the excited state and rapidly transfer to the semiconductor while the holes are left in the dye. The electrons pass to the conductive substrate and transfer to the counter electrode through the external circuit. The oxidized dye is restored by the electrolyte, and the oxidized electrolyte accepting electrons from the counter electrode is restored to the ground state, completing the entire electron transfer process.

One of the influencing factors of the photoelectric conversion in dye-sensitized solar cells is the velocity of the electrons migrating to the conductive substrate after the photo-chemical reaction. The electron migration velocity is low, due to certain defects in the single electrode with nanocrystalline semiconductor film. The combined probability of defects with the surrounding electron acceptors (such as the surface state traps on nanocrystalline film and the oxidized electrolyte), increases greatly, reducing photoelectric conversion efficiency. On the other hand, traditional photosensitive dyes were limited by the specific surface area (S, m²/g) of the titanium dioxide layer. Reduced photosensitive dyes adsorbed on the titanium dioxide layer area reduces in turn the number of absorbed photons. The specific surface area is defined as the total surface area occupied by 1 g solid material.

U.S. Pat. No. 5,084,365 entitled “Photo-electrochemical cell and process of making same”, discloses that a photo-electrochemistry device made using the sol-gel method is used to reduce manufacturing costs and improve photoelectric conversion efficiency by controlling surface roughness. However, the surface roughness resulting from the sol-gel method revealed in the patent, is limited. Part of the film with large surface roughness will cause a light scattering effect, and reduce the energy conversion efficiency.

U.S. Pat. No. 6,384,313B2 entitled “Solar cell module and method of producing the same”, discloses forming more than one small battery, connecting the batteries to each other on a single glass, and then packaging them into a solar cell module. The patent disclosed that the production process was almost automatic, requiring precision and expensive equipment. However, the patent did not reveal the method of increasing photosensitive dyes adsorbed on titanium dioxide layer.

### SUMMARY

In view of this, the inventor of the disclosure has studied carefully, and proposes a photo-chemical solar cell with nanoneedle electrode and method manufacturing the same to improve conversion efficiency or eliminate the disadvantages of conventional dye-sensitized solar cells. Using a innovative preparation method, the semiconductor thin films can develop an nanoneedle structure at a lower temperature. Using this method, the semiconductor thin film with an nanoneedle structure can combine effectively with a photosensitive layer. The disclosure refers to U.S. Pat. No. 5,084,365 Notice and U.S. Pat. No. 6,384,313 B2 Notice as cited references.

The disclosure is to provide a photo-chemical solar cell with nanoneedle electrode. The nanoneedle electrode increases the specific surface area of the semiconductor thin film, which can combine effectively with the photosensitive layer, increasing photon absorption and improving its electronic conduction rate.

The disclosure is also to provide a manufacturing method of a photo-chemical solar cell with nanoneedle electrode. The semiconductor thin films can develop an nanoneedle structure at a lower temperature and increase the specific surface area, which can combine with the photosensitive layer effectively, increasing the photon absorption and improving the electronic conduction rate.

The disclosure provides a photo-chemical solar cell with nanoneedle electrode, including a first conductive substrate, a working electrode, a photosensitive layer, a second conductive substrate, a counter electrode and a electrolyte layer. The working electrode with the pores between 5 nm and 25 nm is placed on the top of the first conductive substrate, formed from a semiconductor oxide layer with nanoneedle structure. The semiconductor oxide layer with nanoneedle structure is composed from an organometallic compounds and a hydrocarbon compound. The photosensitive layer is adsorbed on the working electrode. The second conductive substrate is placed on the top of the photosensitive layer. The counter electrode is placed between the second conductive substrate and the photosensitive layer. The electrolyte layer is filled between the working electrode and the counter electrode.

To achieve the secondary objective, the disclosure provides a manufacturing method of a photo-chemical solar cell with nanoneedle electrode, including the following steps: providing a first conductive substrate; placing a working electrode on the first conductive substrate, with the pores between 5 nm and 25 nm, formed from a semiconductor oxide layer with nanoneedle structure which is composed of an organometallic compound and a hydrocarbon compound; providing a photosensitive layer which is adsorbed on the working electrode; placing a second conductive substrate on the top of the photosensitive layer; placing a counter electrode between the second conductive substrate and the photosensitive layer; and filling a electrolyte layer between the working electrode and the counter electrode.

### BRIEF DESCRIPTION OF THE DRAWINGS

All the objects, advantages, and novel features of the invention will become more apparent from the following detailed description when taken in conjunction with the accompanying drawing.

FIG. 1 is the photo-chemical solar cell with nanoneedle electrode of the first embodiment of the disclosure; and

FIG. 2 is the photo-chemical solar cell with nanoneedle electrode of the second embodiment of the disclosure.

### DETAILED DESCRIPTION

Although the invention has been explained in relation to several preferred embodiments, the accompanying drawings and the following detailed descriptions are the preferred embodiment of the disclosure. It is to be understood that the following disclosed descriptions will be examples of the disclosure, and will not limit the disclosure to the drawings and the special embodiment.

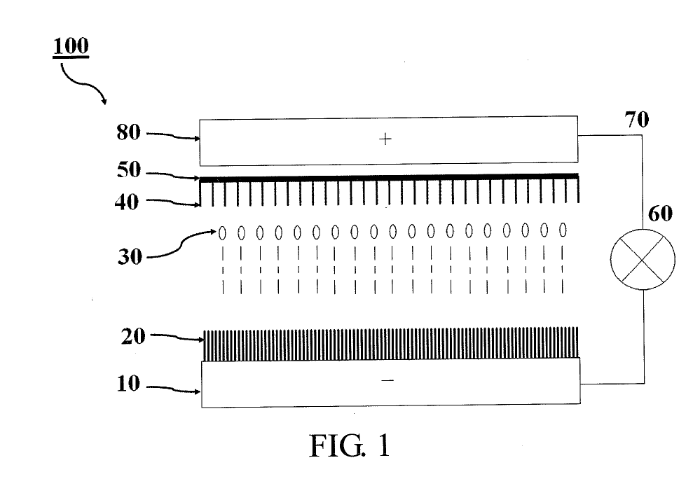

The disclosure reveals a structure of the photo-chemical solar cell with nanoneedle electrode 100. Please refer to FIG. 1, which shows the scheme of the photo-chemical solar cell with nanoneedle electrode 100 of the first embodiment of the disclosure. As shown in FIG. 1, the photo-chemical solar cell with nanoneedle electrode 100 includes a first conductive substrate 10, a working electrode 20, a photosensitive layer 30, an electrolyte layer 40, a counter electrode 50 and a second conductive substrate 80.

The first conductive substrate 10 and the second conductive substrate 80 can be indium-doped tin oxide (ITO) thin film coated glass substrates, fluorine-doped tin oxide (FTO) thin film coated glass substrates, indium-doped tin oxide (ITO) thin film coated flexible substrates, fluorine-doped tin oxide (FTO) thin film coated flexible substrates or conductive metals such as stainless steel. In the disclosure, using the fluorine-doped tin oxide thin film will increase the conductivity of the first conductive substrate 10 and the second conductive substrate 80.

In the disclosure, the working electrode 20 composed of the metal oxide with the semiconductor properties, such as TiO₂, ZnO or SnO, is placed on the top of the first conductive substrate 10. The requirements of the working electrode 20 are (1) high specific surface area, (2) porosity, (3) high conductivity, (4) transparent and (5) high stability.

It should be noted that the working electrode 20 is an nanoneedle electrode composed of the metal oxide with nanoneedle structure, such as nanorods or nanowires, the diameter of the rod or wire decreases gradually from the bottom to the top.

The photosensitive layer 30 adsorbed on the working electrode 20 is selected from a group consisting of squaric acid dyes, merocyanine dyes, rhodamine dyes, azobenzene dyes, semi-cyanine dyes or metal complexes. The metal complexes can be ruthenium complexes, such as N3, N719, black dyes and other commercial dyes.

The second conductive substrate 80 is placed on the top of the photosensitive layer, and the counter electrode 50 is placed between the second conductive substrate and the photosensitive layer 30. The counter electrode can be a conductive carbon or metal layer, such as platinum or gold. The electrolyte layer 40 is filled between the working electrode 20 and the counter electrode 50, which mainly provides the redox reaction. An electrolyte containing iodine ions is most commonly used. Other kinds of solid electrolyte and quasi-solid electrolyte can also be used in the disclosure. Above all, liquid electrolytes (I⁻/I₃⁻) have the highest efficiency.

After absorbing the photon energy, the dye molecules of the photosensitive layer 30 adsorbed on the working electrode 20 inject the electrons quickly into the working electrode 20 close by. The lost electrons in the photosensitive layer 30 can be quickly compensated from the electrolyte layer 40, and the electrons entering the working electrode 20 can charge the load 60 through the external wire 70. Finally, a cycle is formed while the electrons reach the counter electrode 50.

Further features of the first embodiment of the disclosure will now be illustrated, namely the working electrode 20 with nanoneedle structure. In the disclosure, it is better to compose the nanoneedle electrode as the working electrode 20 from nanoneedle titanium dioxide. Next, the nanoneedle titanium dioxide layer will be used as an example to illustrate the nanoneedle electrode. However, it should be noted that the nanoneedle electrode is not limited to the nanoneedle titanium dioxide layer. The titanium dioxide with nanoneedle structure with pore size between 5 nm and 25 nm is prepared using the sol-gel method. Using the sol-gel method, the titanium dioxide is compounded from an organometallic compound and a hydrocarbon compound at a temperature between 25° C. and 100° C.

The nanoneedle titanium dioxide layer as the working electrode 20 is best prepared using the sol-gel method. The sol-gel method includes the following steps:

1. Putting a metal organic compound and a hydrocarbon compound (by means of chemical synthesis), into the reacting system the temperature of which is between 25° C. and 200° C.;

2. Forming a solution (composed of the organometallic compound and the hydrocarbon compound), and putting the first conductive substrate 10 into the solution to form a semiconductor thin film; and

3. Heating the semiconductor thin film to a temperature sufficient to form the nanoneedle structure on the semiconductor thin film.

In the disclosure, the organometallic compound is M-X, where the M is a metal such as Ti, Zn, Sn; and the X is the organic group. The hydrocarbon is selected from a group consisting of C₂H₅OH, C₃H₇OH, C₄H₉OH, CH₃OC₂H₅, CH₂O, C₃H₃O, C₂H₂(OH)₂, and the temperature is between 300° C. and 1000° C. It should be noted that a better temperature is between 400° C. and 600° C., and the ideal temperature is between 400° C. and 500° C. The nanoneedle titanium dioxide layer, the pore size of which is between 5 nm and 15 nm, and the average roughness of which is between 2 nm and 20 nm, has plural nanoneedle objects with a length ranging from 10 nm to 5 μM.

In order to achieve superior resuilts, it is necessary that the nanoneedle titanium dioxide layer as the working electrode 20 is imposed by a heating energy to form the nanoneedle structure of the titanium dioxide semiconductor thin film. The heating temperature is between 300° C. and 700° C., and applied to the surface modification by applying a plasma and a laser to the semiconductor oxide layer in order to enhance mechanical strength and the acid and base resistance.

In addition, as the nanoneedle structure becomes smaller, the specified surface area will increase significantly; that is, the percentage of the surface atom numbers will increase significantly. A particle with a 10 nm diameter has about 15% of its atoms located on the particle surface, while almost all of the atoms on a nanoparticle with a 1 nm diameter are surface atoms. The specified surface area S of the titanium dioxide layer will rise to 80 m²/g or more, which can improve the adsorption of the photosensitive dyes and thereby increase the number of absorbed photons. Furthermore, the titanium dioxide layer's nanoneedle structure will improve its electronic conduction rate.

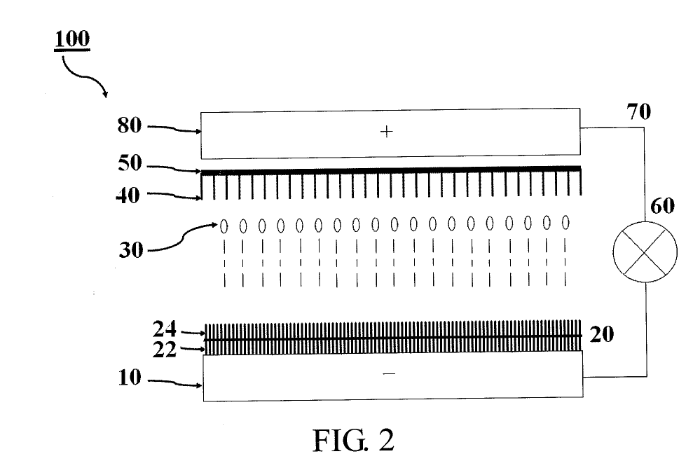

Please refer to FIG. 2, which shows a structure diagram of the photo-chemical solar cell 100 with nanoneedle electrode of the second embodiment of the disclosure. The structure is broadly similar to the first embodiment. The main difference is that the working electrode 20 consists of a first semiconductor thin film 22 with dense structure and a second semiconductor thin film 24 with nanoneedle structure. The so-called dense structure here refers to the thin film having more continuous grain structure and crystallinity. It must be noted that the first semiconductor thin film 22 and the second semiconductor thin film 24 with nanoneedle structure are the same kind of thin film; it is better to use titanium dioxide. Features of the second embodiment of the disclosure, that is, the working electrode 20 with nanoneedle structure, will now be illustrated further.

In this embodiment it is better to compose the nanoneedle electrode as the working electrode 20, from nanoneedle titanium dioxide. The nanoneedle titanium dioxide layer will be used as an example to illustrate the nanoneedle electrode. However, it should be noted that the nanoneedle electrode is not limited to the nanoneedle titanium dioxide layer. The titanium dioxide with nanoneedle structure of a pore size between 5 nm and 25 nm is prepared using the sol-gel method. Using the sol-gel method, the titanium dioxide is composed from an organometallic compound and a hydrocarbon compound, at a temperature between 25° C. and 100° C.

It is better to prepare the nanoneedle titanium dioxide layer as the working electrode using the sol-gel method. The sol-gel method includes the following steps:

1. Putting a metal organic compound and a hydrocarbon compound (using chemical synthesis), into a reacting system at a temperature between 25° C. and 200° C.;

2. Forming a solution (composed of the organometallic compound and the hydrocarbon compound), and putting the first conductive substrate 10 into the solution to form the first semiconductor thin film;

3. Heating the semiconductor thin film with a first temperature to form the dense structure on the first semiconductor thin film, and then dipping the first semiconductor thin film into the solution to form the second semiconductor thin film; and

4. Heating the second semiconductor thin film with the second temperature to form the nanoneedle structure on the second semiconductor thin film.

In the disclosure, the organometallic compound is M-X, where the M is the metal such as Ti, Zn, Sn; and the X is the organic group. The hydrocarbon is selected from a group consisting of C₂H₅OH, C₃H₇OH, C₄H₉OH, CH₃OC₂H₅, CH₂O, C₃H₃O, C₂H₂(OH)₂, and the first and the second temperature are between 300° C. and 1000° C. It should be noted that the better temperature of the first and the second temperature is between 400° C. and 500° C. The nanoneedle titanium dioxide layer has nanoneedle objects with a length ranging from 10 nm to 5 μm. The nanoneedle titanium dioxide layer is formed by coating the second semiconductor thin film 24 on the top of the first semiconductor thin film 22. The pore size of the second semiconductor thin film is between 5 nm and 15 nm, and the average roughness of the first semiconductor thin film is between 2 nm and 20 nm. It should be noted that the second semiconductor thin film contacts with the electrolyte layer 40 and the first semiconductor thin film 22 contacts with the first conductive substrate 10. It is best that the nanoneedle titanium dioxide layer as the working electrode 20 is imposed by a heating energy to form the nanoneedle structure of the titanium dioxide semiconductor thin film. The heating temperature is between 300° C. and 700° C., applied to the surface modification by applying a plasma and a laser to the semiconductor oxide layer. The specified surface area S of the titanium dioxide layer will increase to 80 m²/g or more, which can improve the adsorption of the photosensitive dyes and thereby increase the number of absorbed photons. Furthermore, the titanium dioxide layer's electronic conduction rate will be improved due to its nanoneedle structure.

The disclosure proposes that photo-chemical solar cell with nanoneedle electrode can be further cascaded in series to form a module. The aforementioned cascaded photo-chemical solar cell connects the negative electrode of the previous battery with the positive electrode of next battery, to form the photo-chemical solar cell modules.

In order to analyze the pores ratio of the nanoneedle titanium dioxide layer of the working electrode 20, heat the first semiconductor thin film and the second semiconductor thin film at different temperatures, and use the UV light to irradiate the first semiconductor thin film and the second semiconductor thin film for 10 minutes to make a pore size analysis. The results are shown in Table I. The greater contact angle indicates more adsorbed photosensitive dyes, indicating more holes.

Table I shows the contact angle of the first semiconductor thin film with the second semiconductor thin film (unit: degrees):

| | Heating temperature (° C.) | | | |
|---|---|---|---|---|
| | 500 | 550 | 650 | 700 |
| the contact angle of the first | 35 | 44 | 55 | 71 |
| semiconductor thin film (unit: degrees) | | | | |
| the contact angle of the second | 39 | 54 | 67 | 75 |
| semiconductor thin film (unit: degrees) | | | | |

The working electrode with the nanoneedle titanium dioxide layer co-operates with FTO coated glass substrate, N3 photosensitive layer, electrolyte (I⁻/I₃⁻) and the counter electrode made from platinum (Pt), are assembled into two FTO coated glass substrate to form a battery. The working electrode of the traditional photo-chemical cell uses traditional material P25 (titanium dioxide with 80% anatase phase and 20% rutile phase), and other materials, and the packaging process is the same as the disclosure. Comparing the photoelectric conversion efficiency of the traditional cell with the photoelectric conversion efficiency of the cell with the working electrode 20 with the nanoneedle titanium dioxide layer, with the traditional cell, the short circuit current density of the disclosure is 20% more than the traditional cell. As the electronic conductivity increases, the photoelectric conversion efficiency increases by about 20%.

The disclosure can make the nanoneedle titanium dioxide layer with nanoneedle electrode by combining the dense semiconductor thin film with the porous-needle semiconductor thin film at a low temperature, which can absorb a large number of photosensitive dyes and thus effectively improve the photoelectric conversion efficiency.

In summary, the disclosure has following advantages and functions:

1. The disclosure provides a photo-chemical solar cell with nanoneedle electrode.

The nanoneedle electrode increases the specific surface area of the semiconductor thin film which can combine effectively with the photosensitive layer and increase photon absorption and improve its electronic conduction rate.

2. The disclosure provides a method of manufacturing the nanoneedle electrode that can form the nanoneedle structure on the semiconductor thin film as the working electrode at a lower temperature.

3. By combining the dense semiconductor thin film with the porous-needle semiconductor thin film, the greater thickness increases the specific surface area, which can adsorb a large number of photosensitive dyes and effectively improve the photoelectric conversion efficiency.

The disclosure also provides a manufacturing method of a photo-chemical solar cell with nanoneedle electrode, including the following steps: providing a first conductive substrate 10; placing a working electrode 20 on the first conductive substrate 10, with the pores between 5 nm and 25 nm, formed from a semiconductor oxide layer with nanoneedle structure which is composed of an organometallic compound and a hydrocarbon compound; providing a photosensitive layer 30 which is adsorbed on the working electrode 20; placing a second conductive substrate 80 on the top of the photosensitive layer 30; placing the counter electrode 50 between the second conductive substrate 80 and the photosensitive layer 30; and filling a electrolyte layer 40 between the working electrode 20 and the counter electrode 50.

The working electrode 20 composed of the metal oxide with semiconductor properties, such as TiO₂, ZnO or SnO, has plural nanoneedle objects with a length ranging from 10 nm to 5 μm.

In addition, the aforementioned semiconductor oxide layer with the nanoneedle structure is an nanoneedle titanium dioxide layer prepared using the sol-gel method described in the first embodiment, which will not be repeated here.

It is better that the nanoneedle titanium dioxide layer as the working electrode is imposed by heating, to form the nanoneedle structure of the titanium dioxide semiconductor thin film. The heating temperature is between 300° C. and 700° C., applied to the surface modification by applying a plasma and a laser to the semiconductor oxide layer.

While the disclosure has been described by way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is :

1. A photo-chemical solar cell with nanoneedle electrode, comprising:
a first conductive substrate;
a working electrode, placed on the first conductive substrate, with the pores between 5 nm and 25 nm, formed from a semiconductor oxide layer with nanoneedle structure which is composed of an organometallic compound and a hydrocarbon compound;
a photosensitive layer, adsorbed on the working electrode;
a second conductive substrate, placed on the top of the photosensitive layer;
a counter electrode, placed between the second conductive substrate and the photosensitive layer; and
a electrolyte layer, filled between the working electrode and the counter electrode.

2. The photo-chemical solar cell with nanoneedle electrode as claimed in claim 1, wherein the semiconductor oxide layer has plural nanoneedle objects with a length ranging from 10 nm and 5 μm.

3. The photo-chemical solar cell with nanoneedle electrode as claimed in claim 1, wherein the semiconductor oxide layer is formed by coating a second semiconductor thin film on the top of a first semiconductor thin film, the pore size of the second semiconductor thin film is between 5 nm and 15 nm and the average roughness of the first semiconductor thin film is between 2 nm and 20 nm.

4. The photo-chemical solar cell with nanoneedle electrode as claimed in claim 1, wherein the hydrocarbon compound is selected from the group consisting of C₂H₅OH, C₃H₇OH, C₄H₉OH, CH₃OC₂H₅, CH₂O, C₃H₃O, C₂H₂(OH)₂.

5. A manufacturing method of a photo-chemical solar cell with nanoneedle electrode, comprising the steps of:
providing a first conductive substrate;
placing a working electrode on the first conductive substrate, with the pores between 5 nm and 25 nm, formed from a semiconductor oxide layer with nanoneedle structure which is composed of an organometallic compound and a hydrocarbon compound;
providing a photosensitive layer, adsorbed on the working electrode;
placing a second conductive substrate on the top of the photosensitive layer;
placing a counter electrode between the second conductive substrate and the photosensitive layer; and
filling a electrolyte layer between the working electrode and the counter electrode.

6. The manufacturing method of a photo-chemical solar cell with nanoneedle electrode as claimed in claim 5, wherein the semiconductor oxide layer has plural nanoneedle objects with a length ranging from 10 nm and 5 μm.

7. The manufacturing method of a photo-chemical solar cell with nanoneedle electrode as claimed in claim 5, wherein the semiconductor oxide layer is formed by coating a second semiconductor thin film on the top of a first semiconductor thin film, the pore size of the second semiconductor thin film is between 5 nm and 15 nm and the average roughness of the first semiconductor thin film is between 2 nm and 20 nm.

8. The manufacturing method of a photo-chemical solar cell with nanoneedle electrode as claimed in claim 5, wherein the hydrocarbon is selected from the group consisting of C₂H₅OH, C₃H₇OH, C₄H₉OH, CH₃OC₂H₅, CH₂O, C₃H₃O, C₂H₂(OH)₂.

9. The manufacturing method of a photo-chemical solar cell with nanoneedle electrode as claimed in claim 5, wherein the working electrode needs to be imposed by a heating energy to form the nanoneedle structure of the semiconductor oxide layer.

10. The manufacturing method of a photo-chemical solar cell with nanoneedle electrode as claimed in claim 9, wherein the heating energy is between 300° C. and 700° C., applied to the surface modification by applying a plasma and a laser to the semiconductor oxide layer.
